(19) United States
(12) Patent Application Publication
(10) Pub. No.: US 2026/0255663 A1
(43) Pub. Date: Aug. 27, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Shunsuke ASABA, Himeji Hyogo (JP); Kyungpil NAM, Himeji Hyogo (JP); Hiroshi KONO, Himeji Hyogo (JP)

(21) Appl. No.: 19/445,392

(22) Filed: Jan. 9, 2026

(30) Foreign Application Priority Data
Feb. 26, 2025 (JP) 2025-028905

(51) Int. Cl. H10D 84/00; H10D 62/832

(52) U.S. Cl. CPC H10D 84/146; H10D 62/8325

(57) ABSTRACT

A semiconductor device includes a first electrode, a second electrode, and a silicon carbide layer between the first and second electrodes. The silicon carbide layer includes a first silicon carbide region of a first conductivity type that is in contact with the first electrode and extends in a first direction, second, third, and fourth silicon carbide regions of a second conductivity type that extend in the first direction between the first silicon carbide region and the first electrode, a fifth silicon carbide region of the first conductivity type between the second silicon carbide region and the first electrode, and a sixth silicon carbide region of the second conductivity type that is between and in contact with the second and third silicon carbide regions. The device also includes a first gate electrode extending in the first direction and facing the second, third, and sixth silicon carbide region.

### CROSS-REFERENCE TO RELATED APPLICATIONS

This application is based upon and claims the benefit of priority from Japanese Patent Application No. 2025-028905, filed on February 26, 2025, the entire contents of which are incorporated herein by reference.

### FIELD

Embodiments relate to a semiconductor device.

### BACKGROUND

A vertical MOSFET using silicon carbide has a pn junction diode as an internal diode. For example, the MOSFET is used as a switching element connected to an inductive load. In this case, even when the MOSFET is off, a reflux current can flow through the internal diode.

However, when the reflux current flows through the internal diode, there is a problem that stacking faults grow in the silicon carbide layer due to the carrier recombination energy, thereby increasing the on-resistance of the MOSFET. The increase in the on-resistance of the MOSFET leads to a decrease in the reliability of the MOSFET. For example, by providing a Schottky Barrier Diode (SBD) that operates unipolarly as the internal diode in the MOSFET, it is possible to suppress the growth of stacking faults in the silicon carbide layer. By providing an SBD as the internal diode in the MOSFET, the reliability of the MOSFET is improved.

When a large surge voltage exceeding the steady state is instantaneously applied between the electrodes of the MOSFET, a large surge current accompanying the surge voltage may flow. When such a large surge current flows, the MOSFET generates heat and the MOSFET may be destroyed. The maximum allowable peak current value (I_{FSM}), which is the maximum value of surge current allowed by the MOSFET, is referred to as surge current tolerance. In a MOSFET provided with an SBD, it is desirable to improve the surge current tolerance.

### BRIEF DESCRIPTION OF THE DRAWINGS

FIG. 1 is a schematic top view of the semiconductor device of the first embodiment.

FIG. 2 is a schematic cross-sectional view of a part of the semiconductor device of the first embodiment.

FIG. 3 is a schematic top view of a part of the semiconductor device of the first embodiment.

FIG. 4 is a schematic top view of a part of the semiconductor device of the first embodiment.

FIG. 5 is a schematic cross-sectional view of a part of the semiconductor device of the first embodiment.

FIG. 6 is a schematic cross-sectional view of a part of the semiconductor device of the first embodiment.

FIG. 7 is a schematic cross-sectional view of the semiconductor device of the comparative example.

FIG. 8 is an equivalent circuit diagram of the semiconductor device of the comparative example.

FIG. 9 is an explanatory diagram of the diode operation of the semiconductor device of the comparative example.

FIG. 10 is an explanatory diagram of the diode operation of the semiconductor device of the comparative example.

FIG. 11 is an explanatory diagram of the diode operation of the semiconductor device of the first embodiment.

FIG. 12 is an explanatory diagram of the diode operation of the semiconductor device of the first embodiment.

FIG. 13 is a schematic cross-sectional view of the semiconductor device of the first modification of the first embodiment.

FIG. 14 is a schematic cross-sectional view of the semiconductor device of the second modification of the first embodiment.

FIG. 15 is a schematic cross-sectional view of the semiconductor device of the second modification of the first embodiment.

FIG. 16 is a schematic cross-sectional view of the semiconductor device of the second embodiment.

FIG. 17 is a schematic cross-sectional view of a part of the semiconductor device of the third embodiment.

FIG. 18 is a schematic top view of a part of the semiconductor device of the third embodiment.

FIG. 19 is a schematic top view of a part of the semiconductor device of the third embodiment.

FIG. 20 is a schematic cross-sectional view of a part of the semiconductor device of the third embodiment.

FIG. 21 is a schematic cross-sectional view of a part of the semiconductor device of the third embodiment.

### DETAILED DESCRIPTION

Hereinafter, embodiments will be described with reference to the diagrams. In the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative impurity concentrations of each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentrations can be measured, for example, by SIMS (Secondary Ion Mass Spectrometry). Additionally, the impurity concentrations can be determined, for example, from carrier concentrations obtained by SCM (Scanning Capacitance Microscopy). Furthermore, the depth and thickness of the impurity regions can be determined, for example, from images obtained by SEM (Scanning Electron Microscope) or by SIMS.

### First Embodiment

The semiconductor device of the first embodiment is a planar gate type vertical MOSFET 100 using silicon carbide. The MOSFET 100 of the first embodiment is, for example, a Double Implantation MOSFET (DIMOSFET) formed by ion implantation of the base region and the source region. Additionally, the semiconductor device of the first embodiment includes an SBD (Schottky Barrier Diode) as an internal diode. The MOSFET 100 is a vertical n-channel MOSFET using electrons as carriers.

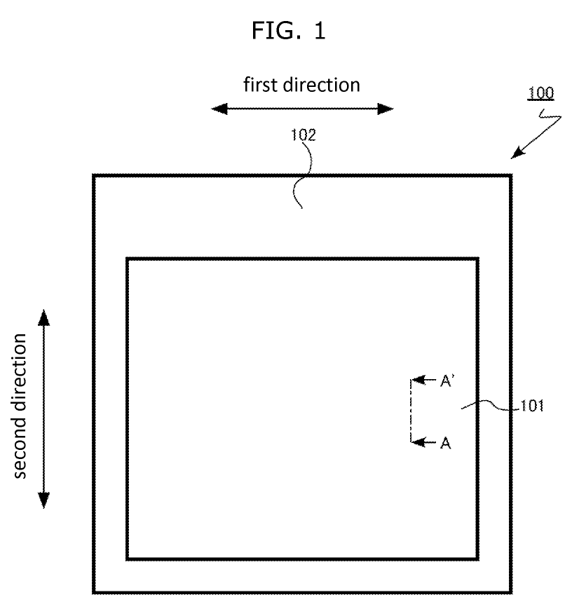

FIG. 1 is a schematic top view of the semiconductor device of the first embodiment. FIG. 1 is a layout diagram of each region provided in the MOSFET 100.

As shown in FIG. 1, the MOSFET 100 includes an element region 101 and a termination region 102.

The element region 101 is provided with a MOSFET and an SBD. The termination region 102 surrounds the element region 101. The termination region 102 is provided with a structure that improves the breakdown voltage of the MOSFET 100. The structure that improves the breakdown voltage of the MOSFET 100 includes, for example, a RESURF or a guard ring.

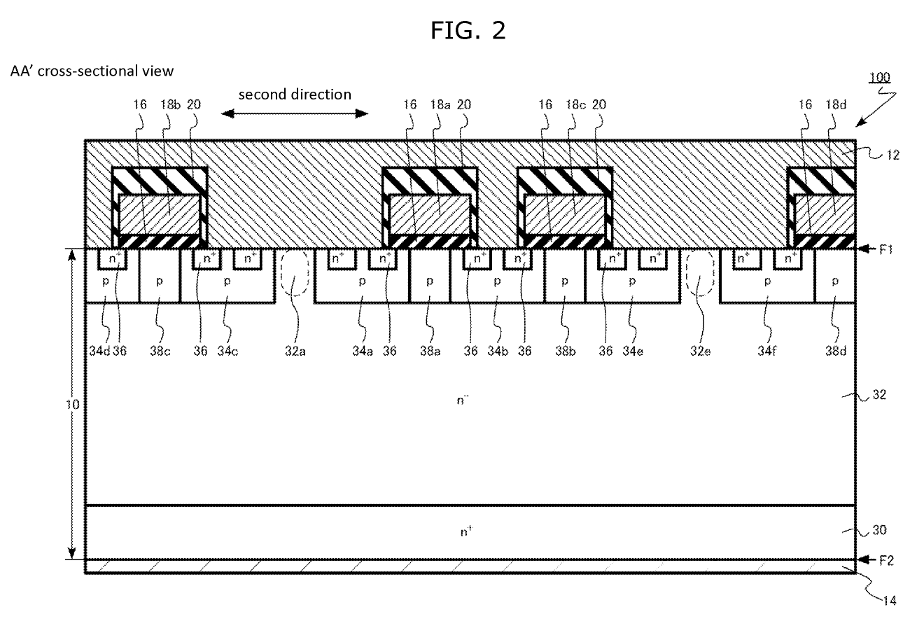

FIG. 2 is a schematic cross-sectional view of a part of the semiconductor device of the first embodiment. FIG. 2 is the AA' cross-section shown in FIGS. 1, 3, and 4.

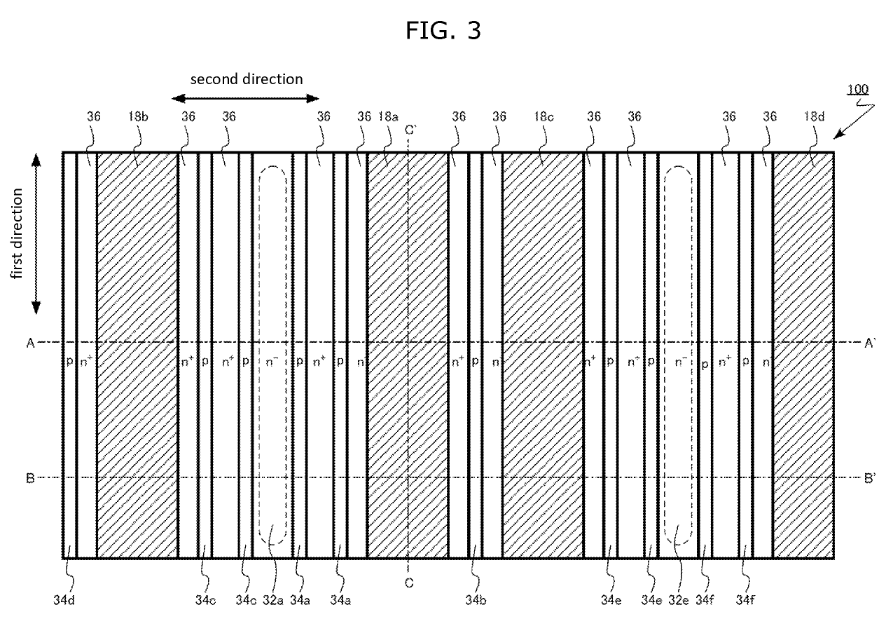

FIG. 3 is a schematic top view of a part of the semiconductor device of the first embodiment. FIG. 3 shows the layout pattern of the gate electrode and the silicon carbide region on the side of the first surface of the silicon carbide layer.

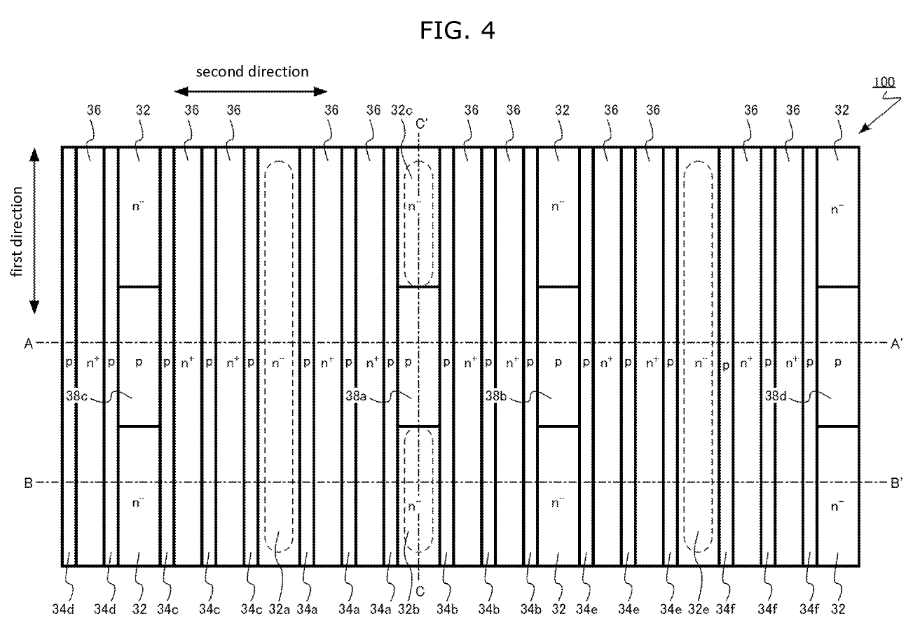

FIG. 4 is a schematic top view of a part of the semiconductor device of the first embodiment. FIG. 4 shows the layout pattern of the silicon carbide region on the side of the first surface of the silicon carbide layer. FIG. 4 is a diagram excluding the gate electrode from FIG. 3.

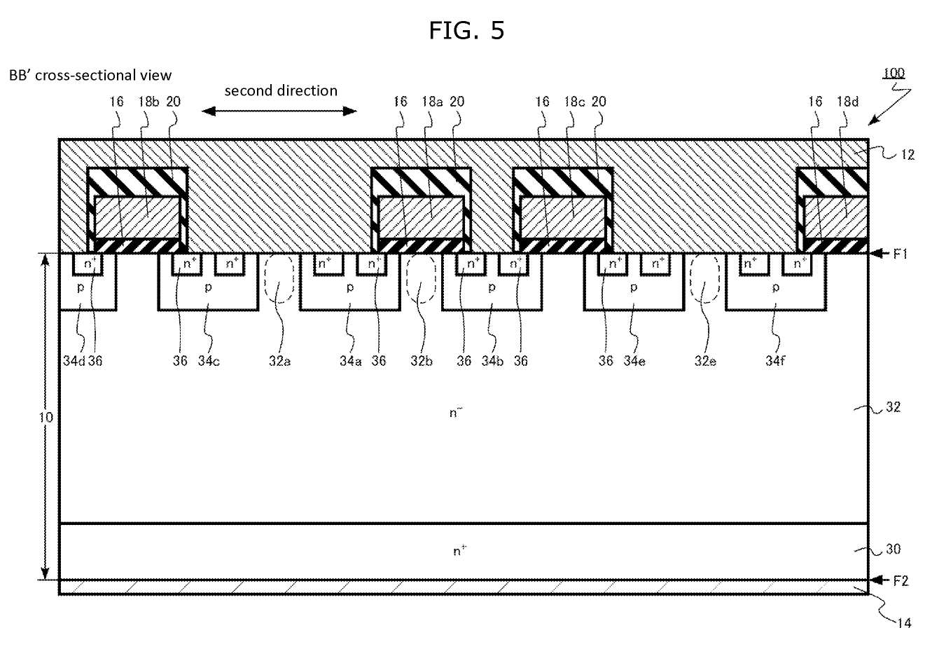

FIG. 5 is a schematic cross-sectional view of a part of the semiconductor device of the first embodiment. FIG. 5 is the BB' cross-section shown in FIGS. 3 and 4.

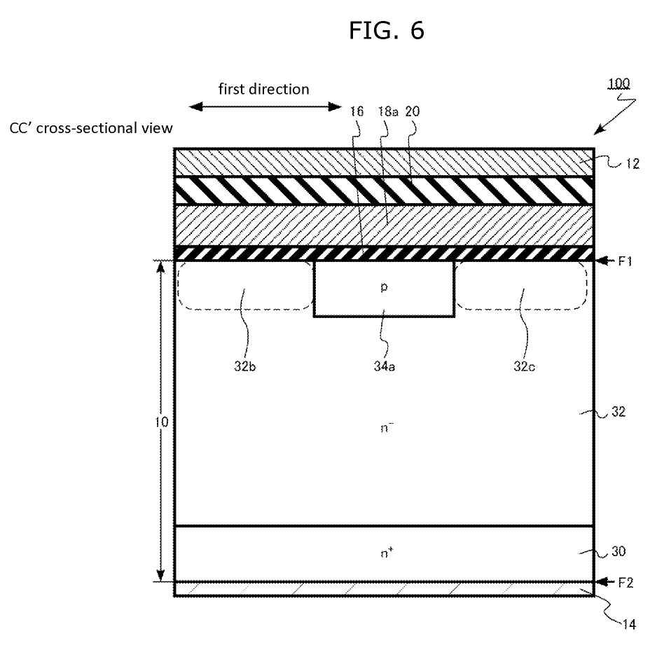

FIG. 6 is a schematic cross-sectional view of a part of the semiconductor device of the first embodiment. FIG. 6 is the CC' cross-section shown in FIGS. 3 and 4.

The MOSFET 100 includes a silicon carbide layer 10, a source electrode 12, a drain electrode 14, a gate insulating layer 16, a first gate electrode 18a, a second gate electrode 18b, a third gate electrode 18c, a fourth gate electrode 18d, and an interlayer insulating layer 20.

Hereinafter, the first gate electrode 18a, the second gate electrode 18b, the third gate electrode 18c, and the fourth gate electrode 18d may be individually or collectively referred to simply as gate electrode 18.

The silicon carbide layer 10 includes an n+ type drain region 30, an n- type drift region 32, a p type first base region 34a, a p type second base region 34b, a p type third base region 34c, a p type fourth base region 34d, a p type fifth base region 34e, a p type sixth base region 34f, an n+ type source region 36, a p type first intermediate region 38a, a p type second intermediate region 38b, a p type third intermediate region 38c, and a p type fourth intermediate region 38d.

The drift region 32 includes a first part 32a, a second part 32b, a third part 32c, and a fifth part 32e.

Hereinafter, the first base region 34a, the second base region 34b, the third base region 34c, the fourth base region 34d, the fifth base region 34e, and the sixth base region 34f may be individually or collectively referred to simply as base region 34. Additionally, the first intermediate region 38a, the second intermediate region 38b, the third intermediate region 38c, and the fourth intermediate region 38d may be individually or collectively referred to simply as intermediate region 38.

The silicon carbide layer 10 is provided between the source electrode 12 and the drain electrode 14. The silicon carbide layer 10 is provided between the gate electrode 18 and the drain electrode 14. The silicon carbide layer 10 is single-crystal SiC. The silicon carbide layer 10 is, for example, 4H-SiC.

The silicon carbide layer 10 includes a first surface (F1 in FIGS. 2, and 5, and 6) and a second surface (F2 in FIGS. 2, 5, and 6). The first surface F1 is the surface of the silicon carbide layer. The second surface F2 is the back surface of the silicon carbide layer. Hereinafter, the first surface F1 may be referred to as the surface, and the second surface F2 may be referred to as the back surface. The first surface F1 is located on the side of the source electrode 12 of the silicon carbide layer 10. The second surface F2 is located on the side of the drain electrode 14 of the silicon carbide layer 10. The first surface F1 and the second surface F2 face each other. Hereinafter, "depth" means the depth in the direction from the first surface to the second surface. The "surface" of the first surface F1 and the second surface F2 refers to, for example, the interface between the silicon carbide layer and the insulating layer, or the interface between the silicon carbide layer and the metal.

The first direction is defined as the direction parallel to the first surface. Additionally, the second direction is defined as the direction perpendicular to the first direction and parallel to the first surface.

FIGS. 2 and 5 are cross-sections perpendicular to the first direction. FIG. 6 is a cross-section perpendicular to the second direction.

The first surface F1 is, for example, a surface inclined at an angle between 0 degrees and 8 degrees relative to the (0001) plane. The second surface F2 is, for example, a surface inclined at an angle between 0 degrees and 8 degrees relative to the (000-1) plane. The (0001) plane is referred to as the silicon face, and the (000-1) plane is referred to as the carbon face.

The thickness of the silicon carbide layer 10 is, for example, between 5 μm and 350 μm.

The n+ type drain region 30 is provided on the back surface side of the silicon carbide layer 10. The drain region 30 contains, for example, nitrogen (N) as an n-type impurity. The n-type impurity concentration of the drain region 30 is, for example, between 1×10¹⁸ cm⁻³ and 1×10²¹ cm⁻³.

The n- type drift region 32 is provided between the drain region 30 and the first surface F1. The drift region 32 is provided between the source electrode 12 and the drain electrode 14. The drift region 32 is provided between the gate electrode 18 and the drain electrode 14.

The drift region 32 is provided between the drain region 30 and the first surface F1. The drift region 32 is provided on the drain region 30.

The drift region 32 contains, for example, nitrogen (N) as an n-type impurity. The n-type impurity concentration of the drift region 32 is lower than that of the drain region 30. The n-type impurity concentration of the drift region 32 is, for example, between 4×10¹⁴ cm⁻³ and 5×10¹⁷ cm⁻³. The thickness of the drift region 32 is, for example, between 3 μm and 100 μm.

The drift region 32 includes a part that contacts the first surface F1. The drift region 32 includes, for example, a first part 32a, a second part 32b, a third part 32c, and a fifth part 32e that contact the first surface F1.

The first part 32a and the fifth part 32e extend in the first direction. The first part 32a and the fifth part 32e contact the source electrode 12.

The first part 32a and the fifth part 32e are provided between two adjacent base regions 34 in the second direction. For example, the first part 32a is provided between the first base region 34a and the third base region 34c. For example, the fifth part 32e is provided between the fifth base region 34e and the sixth base region 34f.

The first part 32a and the fifth part 32e function as n-type semiconductor regions of the SBD.

The second part 32b and the third part 32c are provided between two adjacent base regions 34 in the second direction. The second part 32b and the third part 32c are provided between the first base region 34a and the second base region 34b. The second part 32b and the third part 32c face the first gate electrode 18a.

The second part 32b and the third part 32c function as the path for the on-current when the MOSFET 100 is in the on-state.

The p-type base region 34 is provided between the drift region 32 and the first surface F1. The base region 34 extends in the first direction. The base region 34 is repeatedly arranged in the second direction.

The second base region 34b is provided in the second direction relative to the first base region 34a. The third base region 34c is provided in the second direction relative to the first base region 34a. The first base region 34a is provided between the third base region 34c and the second base region 34b. The first part 32a is provided between the first base region 34a and the third base region 34c.

A part of the base region 34 functions as the channel region of the MOSFET 100. The base region 34 functions as the p-type semiconductor region of the pn junction diode.

The base region 34 contains, for example, aluminum (Al) as a p-type impurity. The p-type impurity concentration of the base region 34 is, for example, between 5×10¹⁷ cm⁻³ and 1×10²¹ cm⁻³. The p-type impurity concentration of the base region 34 is defined as the p-type impurity concentration at the midpoint of the depth of the base region 34.

The depth of the base region 34 is, for example, between 0.3 μm and 1.0 μm.

The base region 34 is electrically connected to the source electrode 12. The base region 34 is fixed to the potential of the source electrode 12.

The n+ type source region 36 is provided between the base region 34 and the first surface F1. The source region 36 is provided, for example, between the first base region 34a and the first surface F1. The source region 36 extends, for example, in the first direction.

The source region 36 contains, for example, phosphorus (P) as an n-type impurity. The n-type impurity concentration of the source region 36 is higher than that of the drift region 32.

The n-type impurity concentration of the source region 36 is, for example, between 1×10¹⁸ cm⁻³ and 1×10²¹ cm⁻³. The depth of the source region 36 is shallower than that of the base region 34. The depth of the source region 36 is, for example, between 0.1 μm and 0.3 μm.

The source region 36 is electrically connected to the source electrode 12. The source region 36 is fixed to the potential of the source electrode 12.

The p-type intermediate region 38 is provided between the drift region 32 and the first surface F1. The intermediate region 38 faces the gate electrode 18. The intermediate region 38 is provided between two base regions 34 facing the same gate electrode 18. The intermediate region 38 contacts the two base regions 34.

For example, the first intermediate region 38a faces the first gate electrode 18a. The first intermediate region 38a is provided between the first base region 34a and the second base region 34b. The first intermediate region 38a contacts the first base region 34a and the second base region 34b.

For example, the second intermediate region 38b faces the third gate electrode 18c. The second intermediate region 38b is provided between the second base region 34b and the fifth base region 34e. The second intermediate region 38b contacts the second base region 34b and the fifth base region 34e.

For example, the third intermediate region 38c faces the second gate electrode 18b. The third intermediate region 38c is provided between the fourth base region 34d and the third base region 34c. The third intermediate region 38c contacts the fourth base region 34d and the third base region 34c.

The intermediate region 38 is provided between parts of the drift region 32 in the first direction. The intermediate region 38 contacts parts of the drift region 32 in the first direction.

For example, the first intermediate region 38a is provided between the second part 32b and the third part 32c of the drift region 32. The first intermediate region 38a contacts the second part 32b and the third part 32c.

The intermediate region 38 functions as the p-type semiconductor region of the pn junction diode.

The intermediate region 38 contains, for example, aluminum (Al) as a p-type impurity. The p-type impurity concentration of the intermediate region 38 is, for example, substantially equal to the p-type impurity concentration of the base region 34. The p-type impurity concentration of the intermediate region 38 is, for example, between 5×10¹⁷ cm⁻³ and 1×10²¹ cm⁻³. The p-type impurity concentration of the intermediate region 38 is defined as the p-type impurity concentration at the midpoint of the depth of the base region 34.

The depth of the intermediate region 38 is, for example, substantially the same as the depth of the base region 34. The depth of the intermediate region 38 is, for example, between 0.3 μm and 1.0 μm.

The intermediate region 38 is electrically connected to the source electrode 12. The intermediate region 38 is fixed to the potential of the source electrode 12.

The gate electrode 18 is provided on the side of the first surface F1 of the silicon carbide layer 10. The gate electrode 18 extends in the first direction. The gate electrode 18 is arranged in multiple parallel lines in the second direction. The gate electrode 18 has a so-called stripe shape.

The gate electrode 18 is a conductive layer. The gate electrode 18 is, for example, polycrystalline silicon containing p-type or n-type impurities.

The gate electrode 18 faces, for example, the part of the base region 34 that contacts the first surface F1. The gate electrode 18 faces, for example, the part of the intermediate region 38 that contacts the first surface F1. The gate electrode 18 faces, for example, the part of the drift region 32 that contacts the first surface F1.

For example, the first gate electrode 18a faces the first base region 34a. The first gate electrode 18a faces the second base region 34b. The first gate electrode 18a faces the first intermediate region 38a. The first gate electrode 18a faces the second part 32b of the drift region 32. The first gate electrode 18a faces the third part 32c of the drift region 32.

The gate insulating layer 16 is provided between the gate electrode 18 and the silicon carbide layer 10. The gate insulating layer 16 is provided between the gate electrode 18 and the base region 34. The gate insulating layer 16 is provided between the gate electrode 18 and the drift region 32.

For example, the gate insulating layer 16 is provided between the first gate electrode 18a and the first base region 34a. The gate insulating layer 16 is provided between the first gate electrode 18a and the second base region 34b. The gate insulating layer 16 is provided between the first gate electrode 18a and the first intermediate region 38a. The gate insulating layer 16 is provided between the first gate electrode 18a and the second part 32b of the drift region 32. The gate insulating layer 16 is provided between the first gate electrode 18a and the third part 32c of the drift region 32.

The gate insulating layer 16 is, for example, silicon oxide. The gate insulating layer 16 can be applied with, for example, High-k insulating material (high dielectric constant insulating material).

The interlayer insulating layer 20 is provided on the gate electrode 18 and the silicon carbide layer 10. The interlayer insulating layer 20 is provided between the gate electrode 18 and the source electrode 12. The interlayer insulating layer 20 is, for example, silicon oxide.

The interlayer insulating layer 20 functions to electrically separate the gate electrode 18 and the source electrode 12.

The source electrode 12 is provided on the side of the first surface F1 of the silicon carbide layer 10. The source electrode 12 contacts the first surface F1.

The source electrode 12 is electrically connected to the drift region 32, the base region 34, the source region 36, and the intermediate region 38. The source electrode 12 contacts, for example, the drift region 32, the base region 34, and the source region 36. The source electrode 12 contacts, for example, the first part 32a and the fifth part 32e of the drift region 32.

The source electrode 12 contains metal. The metal forming the source electrode 12 is, for example, a laminated structure of titanium (Ti) and aluminum (Al).

The part of the source electrode 12 that contacts the base region 34 and the source region 36 is, for example, metal silicide. The metal silicide is, for example, titanium silicide or nickel silicide.

The part of the source electrode 12 that contacts the drift region 32 does not have metal silicide. The part of the source electrode 12 that contacts the first part 32a and the fifth part 32e does not have metal silicide.

The junction between the base region 34 and the source region 36 and the source electrode 12 is, for example, an ohmic junction. The junction between the drift region 32 and the source electrode 12 is, for example, a Schottky junction. The junction between the first part 32a and the fifth part 32e and the source electrode 12 is, for example, a Schottky junction.

The drain electrode 14 is provided on the side of the second surface F2 of the silicon carbide layer 10. The drain electrode 14 contacts the second surface F2. The drain electrode 14 contacts the drain region 30.

The drain electrode 14 is, for example, metal or a metal semiconductor compound. The drain electrode 14 contains, for example, at least one material selected from the group consisting of nickel silicide, titanium (Ti), nickel (Ni), silver (Ag), and gold (Au).

The junction between the drain region 30 and the drain electrode 14 is, for example, an ohmic junction.

Next, the operation and effects of the MOSFET 100 of the first embodiment will be described.

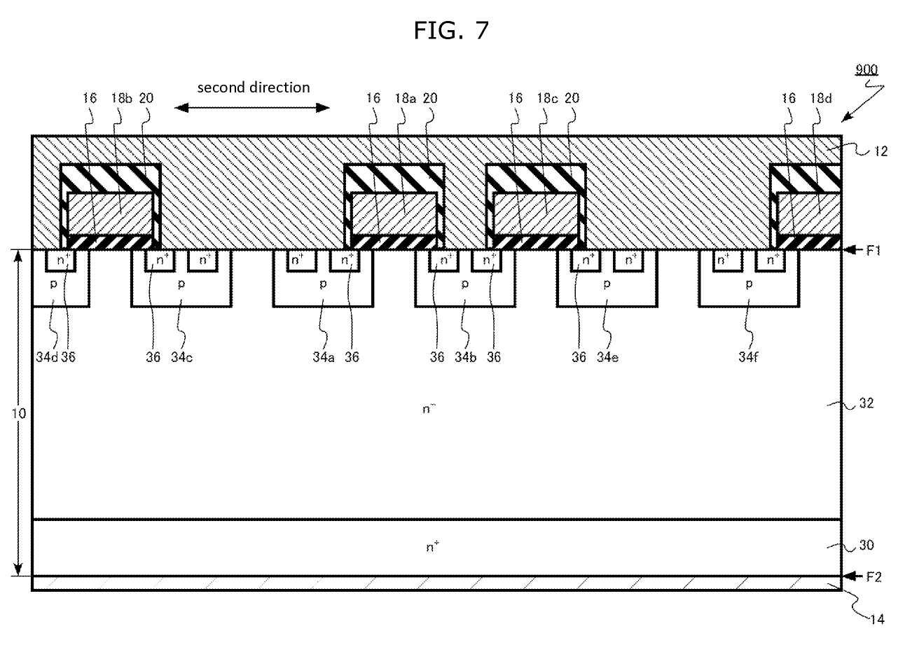

FIG. 7 is a schematic cross-sectional view of the semiconductor device of the comparative example. FIG. 7 corresponds to FIG. 2 of the first embodiment.

The semiconductor device of the comparative example is MOSFET 900. MOSFET 900 differs from the MOSFET 100 of the first embodiment in that the silicon carbide layer 10 does not have an intermediate region 38.

Since MOSFET 900 does not have an intermediate region 38, the drift region 32 is always provided between two adjacent base regions 34. In MOSFET 900, the drift region 32 is always provided between two base regions 34 facing the same gate electrode 18.

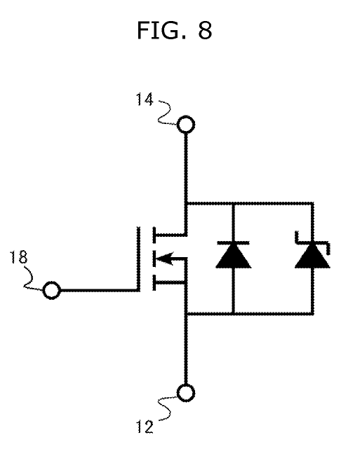

FIG. 8 is an equivalent circuit diagram of the semiconductor device of the comparative example. A pn junction diode and an SBD are connected in parallel to the transistor as internal diodes between the source electrode 12 and the drain electrode 14.

For example, consider the case where MOSFET 900 is used as a switching element connected to an inductive load. When MOSFET 900 is off, a voltage may be applied to the source electrode 12 relative to the drain electrode 14 due to the load current caused by the inductive load. In this case, a forward current flows through the internal diode. This state is also referred to as the reverse conduction state.

The forward voltage (Vf) at which the forward current starts to flow through the SBD is lower than the forward voltage (Vf) at which the forward current starts to flow through the pn junction diode. Therefore, the forward current first flows through the SBD.

The forward voltage (Vf) of the SBD is, for example, 1.0V. The forward voltage (Vf) of the pn junction diode is, for example, 2.5V.

The SBD operates unipolarly. Therefore, even if a forward current flows, stacking faults do not grow in the silicon carbide layer 10 due to the carrier recombination energy.

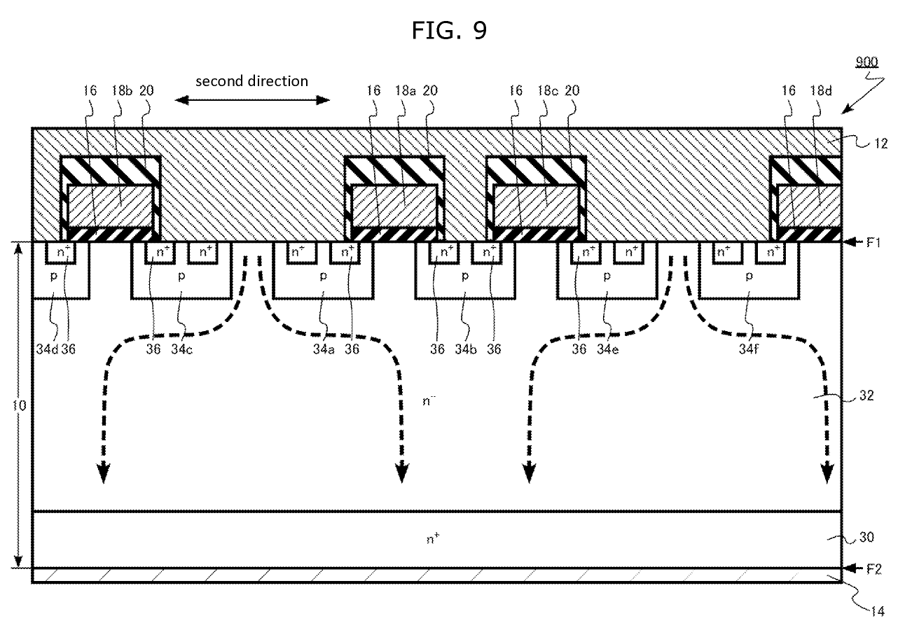

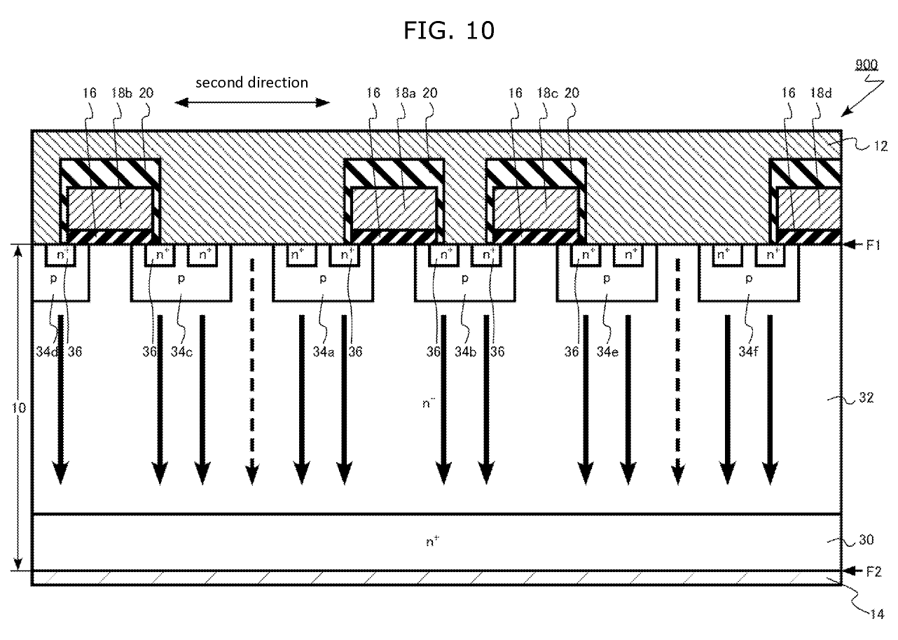

FIGS. 9 and 10 are explanatory diagrams of the diode operation of the semiconductor device of the comparative example. FIGS. 9 and 10 are schematic cross-sectional views of the semiconductor device of the comparative example. FIGS. 9 and 10 correspond to FIG. 7.

FIGS. 9 and 10 show the current flowing through the built-in diode of the MOSFET 900 of the comparative example. FIG. 9 shows the state where only the forward current flows through the SBD, and FIG. 10 shows the state where the forward current flows through both the SBD and the pn junction diode.

That is, FIG. 9 shows the state where the voltage applied between the pn junction of the pn junction diode is lower than the forward voltage (Vf) of the pn junction diode. FIG. 10 shows the state where the voltage applied between the pn junction of the pn junction diode is higher than the forward voltage (Vf) of the pn junction diode.

In FIGS. 9 and 10, the dotted arrow indicates the current flowing through the SBD. In FIG. 10, the solid arrow indicates the current flowing through the pn junction diode.

As shown in FIG. 9, the current flowing through the SBD wraps around the bottom of the base region 34. Therefore, electrostatic potential wraps around the drift region 32 facing the bottom of the base region 34. Due to the wrapping of the electrostatic potential, the voltage applied between the base region 34 and the drift region 32 is reduced.

Therefore, it becomes difficult to exceed the forward voltage (Vf) of the pn junction diode at the bottom of the base region 34. In other words, the operation start voltage of the pn junction diode of the MOSFET 900 of the comparative example is likely to be higher compared to the case where the SBD is not provided. Therefore, the bipolar operation of the pn junction diode is suppressed, and the formation of stacking faults in the silicon carbide layer 10 due to carrier recombination energy is suppressed.

When a large surge voltage exceeding the steady state is momentarily applied between the electrodes of the MOSFET, a large surge current accompanying the surge voltage may flow. The large surge current flows, for example, from the source electrode 12 toward the drain electrode 14.

When the large surge current flows, the MOSFET generates heat and the MOSFET is destroyed. The maximum allowable peak current value (IFSM), which is the maximum value of the surge current allowable for the MOSFET, is called the surge current tolerance. It is desirable to improve the surge current tolerance in the MOSFET provided with the SBD.

When a large surge voltage is applied to the MOSFET 900 of the comparative example, the voltage applied between the pn junction of the pn junction diode becomes higher than the forward voltage (Vf) of the pn junction diode.

When the voltage applied between the pn junction of the pn junction diode becomes higher than the operation start voltage of the pn junction diode, as shown in FIG. 10, current also flows through the pn junction diode. By allowing current to flow through the pn junction diode, a large current can flow through the MOSFET 900, thereby improving the surge current tolerance.

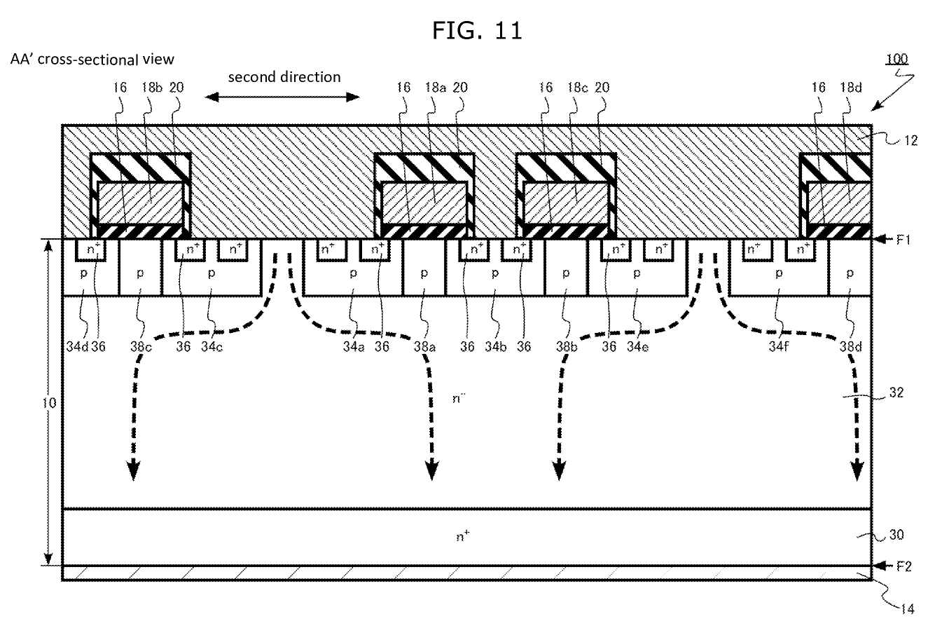

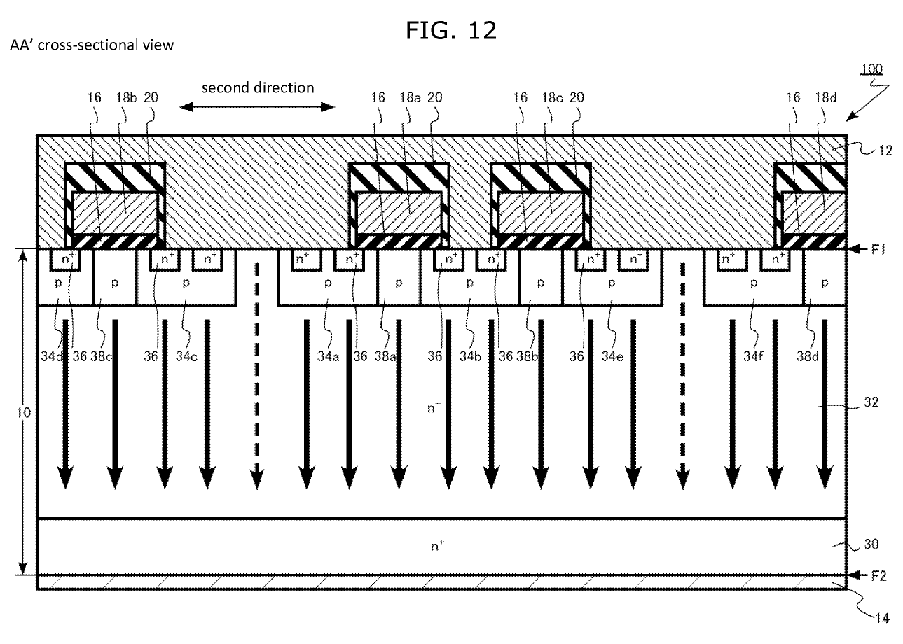

FIGS. 11 and 12 are explanatory diagrams of the diode operation of the semiconductor device of the first embodiment. FIGS. 11 and 12 are schematic cross-sectional views of the semiconductor device of the first embodiment. FIGS. 11 and 12 correspond to FIG. 2. Also, FIGS. 11 and 12 correspond to FIGS. 9 and 10 of the comparative example.

FIGS. 11 and12 show the current flowing through the built-in diode of the MOSFET 100 of the first embodiment. FIG. 11 shows the state where only the forward current flows through the SBD, and FIG. 12 shows the state where the forward current flows through both the SBD and the pn junction diode.

FIG. 11 shows the state where the voltage applied between the pn junction of the pn junction diode is lower than the forward voltage (Vf) of the pn junction diode. In this state, similar to the MOSFET 900 of the comparative example, the voltage applied between the base region 34 and the drift region 32 is reduced due to the wrapping of the electrostatic potential. Therefore, similar to the MOSFET 900 of the comparative example, the bipolar operation of the pn junction diode is suppressed, and the formation of stacking faults in the silicon carbide layer 10 due to carrier recombination energy is suppressed.

FIG. 12 shows the state where the voltage applied between the pn junction of the pn junction diode is higher than the forward voltage (Vf) of the pn junction diode. The MOSFET 100 of the first embodiment includes an intermediate region 38. Therefore, compared to the MOSFET 900 of the comparative example, the effective area of the pn junction becomes larger. Therefore, as shown in FIG. 12, the current flowing through the pn junction diode becomes larger compared to the MOSFET 900 of the comparative example. Thus, the surge current tolerance can be further improved.

According to the first embodiment, it is possible to improve the surge current tolerance in the MOSFET provided with the SBD.

### First Modification

The semiconductor device of the first modification of the first embodiment differs from the semiconductor device of the first embodiment in that the second conductivity type impurity concentration of the sixth silicon carbide region is lower than the second conductivity type impurity concentration of the second silicon carbide region and the second conductivity type impurity concentration of the third silicon carbide region.

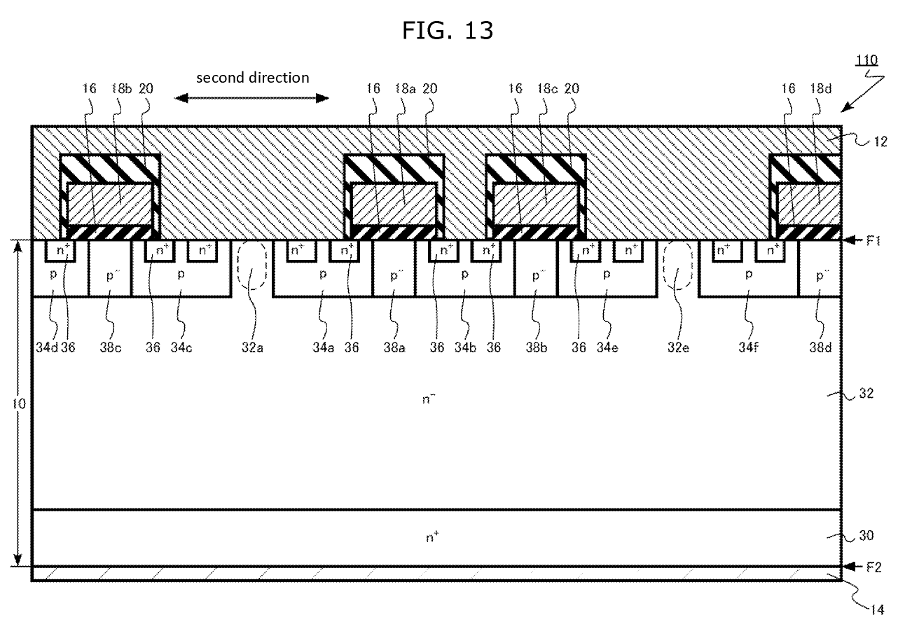

FIG. 13 is a schematic cross-sectional view of the semiconductor device of the first modification of the first embodiment. FIG. 13 corresponds to FIG. 2 of the first embodiment.

The semiconductor device of the first modification of the first embodiment is MOSFET 110.

In MOSFET 110, the p-type impurity concentration of the intermediate region 38 is lower than the p-type impurity concentration of the base region 34. The p-type impurity concentration of the intermediate region 38 is, for example, 20% or more and 90% or less of the p-type impurity concentration of the base region 34. The p-type impurity concentrations of the intermediate region 38 and the base region 34 are defined as the p-type impurity concentration at the position of half the depth of the base region 34.

For example, the p-type impurity concentration of the first intermediate region 38a is 20% or more and 90% or less of the p-type impurity concentration of the first base region 34a and the p-type impurity concentration of the second base region 34b.

According to the first modification of the first embodiment, it is possible to improve the surge current tolerance in the MOSFET provided with the SBD, similar to the first embodiment. Furthermore, by lowering the p-type impurity concentration of the intermediate region 38, for example, when forming the intermediate region 38 using ion implantation, the amount of defects caused by ion implantation damage in the silicon carbide layer 10 can be reduced. Therefore, the reliability of the gate insulating layer 16 provided on the intermediate region 38 is improved.

### Second Modification

The semiconductor device of the second modification of the first embodiment differs from the semiconductor device of the first embodiment in that the silicon carbide layer further includes a seventh silicon carbide region of the first conductivity type provided between the sixth silicon carbide region and the first surface.

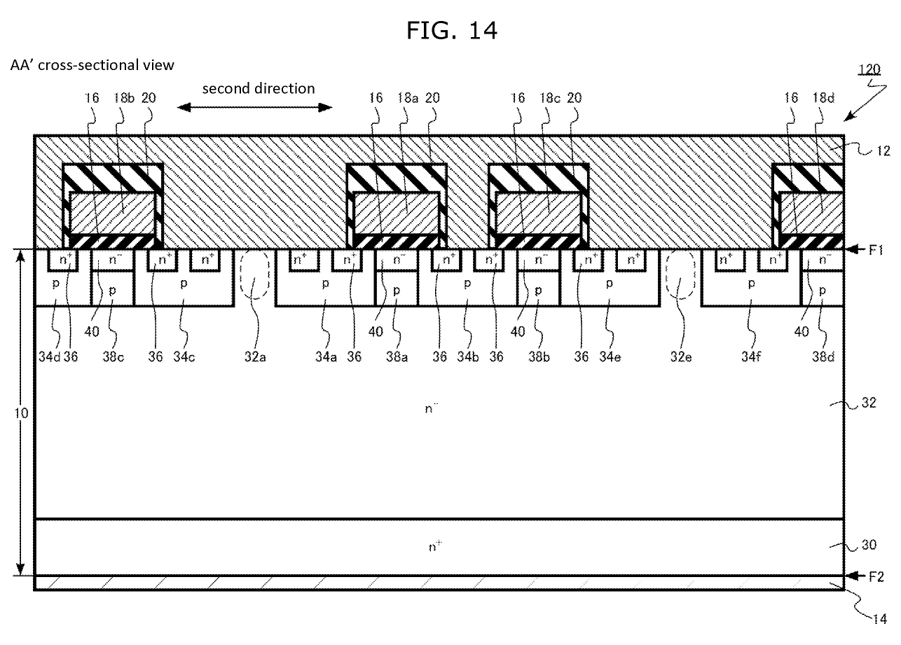

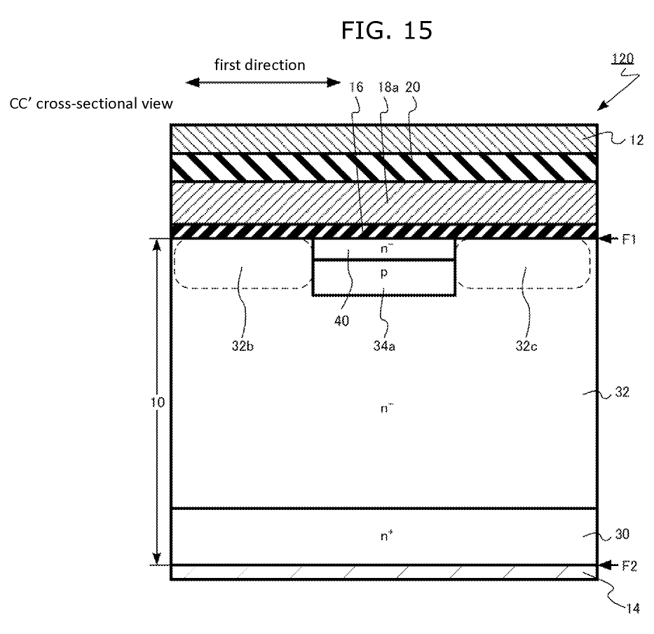

FIGS. 14 and 15 are schematic cross-sectional views of the semiconductor device of the second modification of the first embodiment. FIG. 14 corresponds to FIG. 2 of the first embodiment. FIG. 15 corresponds to FIG. 6 of the first embodiment.

The semiconductor device of the second modification of the first embodiment is MOSFET 120.

The silicon carbide layer 10 of MOSFET 120 differs from MOSFET 100 of the first embodiment in that it further includes an n-type surface region 40.

The n-type surface region 40 is provided between the intermediate region 38 and the first surface F1. The surface region 40 is provided, for example, in the first direction between the second portion 32b of the drift region 32 and the third portion 32c of the drift region 32. The intermediate region 38 is in contact with, for example, the second portion 32b and the third portion 32c.

The surface region 40 functions as the on-current path when MOSFET 120 is in the on-state.

The surface region 40 includes, for example, nitrogen (N) as an n-type impurity. The n-type impurity concentration of the surface region 40 is, for example, 4×10¹⁴ cm⁻³ or more and 5×10¹⁷ cm⁻³ or less.

According to the second modification of the first embodiment, it is possible to improve the surge current tolerance in the MOSFET provided with the SBD, similar to the first embodiment. Furthermore, by providing the surface region 40, the area directly above the intermediate region 38 also functions as the on-current path when MOSFET 120 is in the on-state. Therefore, the on-resistance of MOSFET 120 is reduced.

In summary, according to the first embodiment and its modifications, it is possible to improve the surge current tolerance in the MOSFET provided with the SBD.

### Second Embodiment

The semiconductor device of the second embodiment differs from the semiconductor device of the first embodiment in that the first depth of the sixth silicon carbide region with reference to the first surface is shallower than the second depth of the second silicon carbide region with reference to the first surface and the third depth of the third silicon carbide region with reference to the first surface. Hereinafter, overlapping content with the first embodiment may be partially omitted.

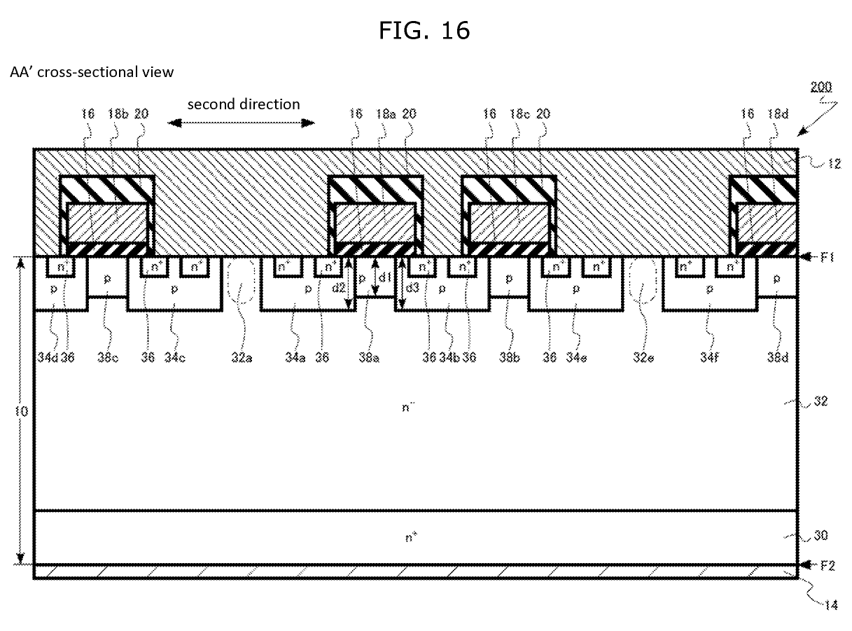

FIG. 16 is a schematic cross-sectional view of the semiconductor device of the second embodiment. FIG. 16 corresponds to FIG. 2 of the first embodiment.

The semiconductor device of the second embodiment is MOSFET 200. In MOSFET 200, the depth of the intermediate region 38 with reference to the first surface F1 is shallower than the depth of the base region 34 with reference to the first surface F1. The depth of the intermediate region 38 with reference to the first surface F1 is, for example, 2/3 or more and 9/10 or less of the depth of the base region 34 with reference to the first surface F1.

For example, the depth of the first intermediate region 38a with reference to the first surface F1 (d1 in FIG. 16) is shallower than the depth of the first base region 34a with reference to the first surface F1 (d2 in FIG. 16) and the depth of the second base region 34b with reference to the first surface F1 (d3 in FIG. 16). Also, for example, the depth d1 of the first intermediate region 38a with reference to the first surface F1 is 2/3 or more and 9/10 or less of the depth d2 of the first base region 34a with reference to the first surface F1 and the depth d3 of the second base region 34b with reference to the first surface F1.

According to the second embodiment, it is possible to improve the surge current tolerance in the MOSFET provided with the SBD, similar to the first embodiment.

Furthermore, by making the depth of the intermediate region 38 with reference to the first surface F1 shallower than the depth of the base region 34 with reference to the first surface F1, irregularities are formed on the pn junction surface, increasing the effective area of the pn junction. Therefore, the current flowing through the pn junction diode increases, thereby further improving the surge current tolerance.

Additionally, by concentrating the current on the irregularities of the pn junction surface, the current flowing through the pn junction diode increases, thereby further improving the surge current tolerance.

In summary, according to the second embodiment, it is possible to improve the surge current tolerance in the MOSFET provided with the SBD, similar to the first embodiment.

It is also possible to combine the components of MOSFET 110 of the first modification or MOSFET 120 of the second modification with MOSFET 200 of the second embodiment.

### Third Embodiment

The semiconductor device of the third embodiment differs from the semiconductor device of the first embodiment in that it further includes a second gate electrode extending in the first direction and facing the fourth silicon carbide region, and the first silicon carbide region further includes a fourth portion extending in the first direction and in contact with the first surface, with the fourth silicon carbide region provided between the fourth portion and the first portion, and the second gate electrode facing the fourth portion. Hereinafter, overlapping content with the first embodiment may be partially omitted.

The semiconductor device of the third embodiment is MOSFET 300.

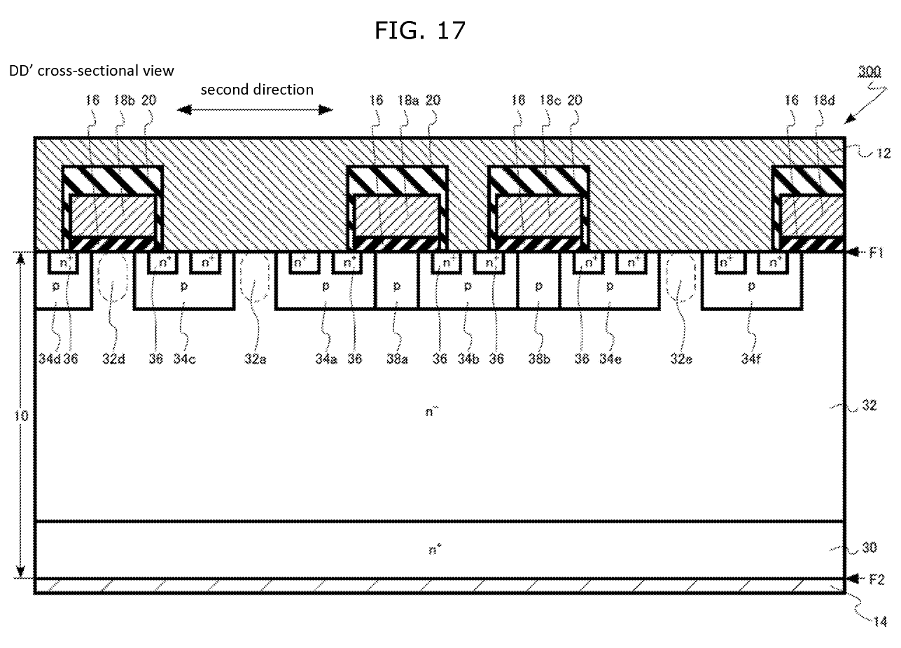

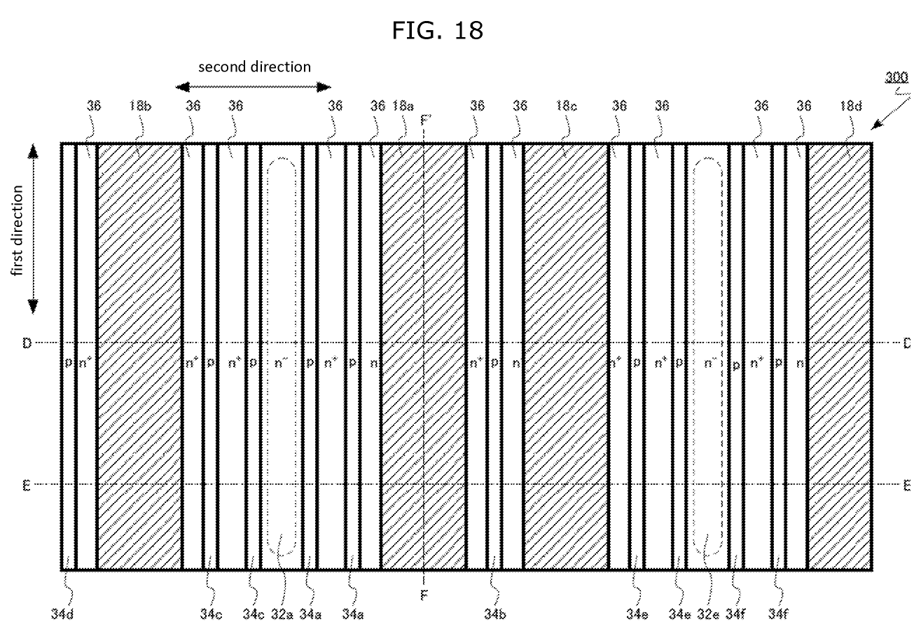

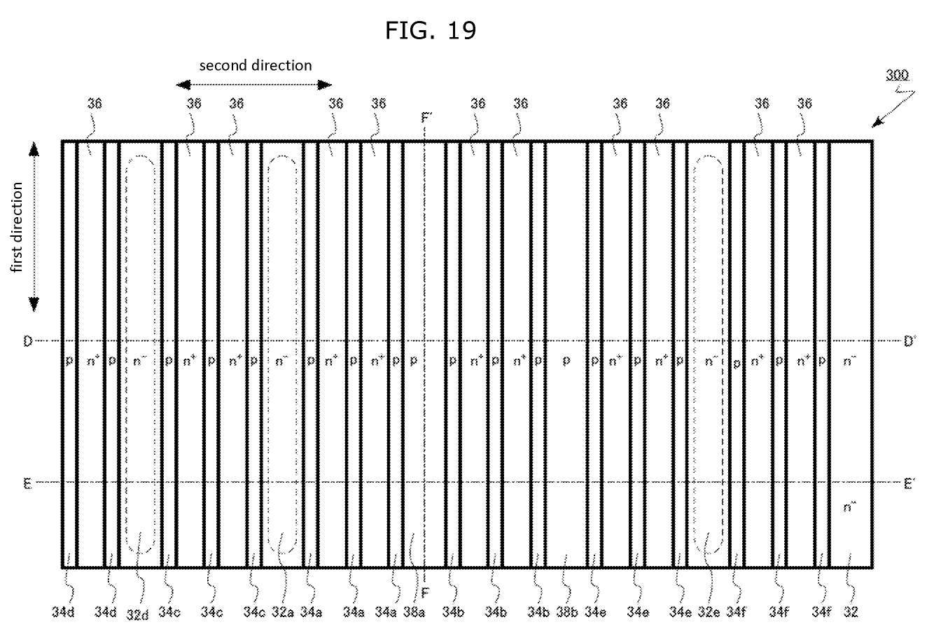

FIG. 17 is a partial schematic cross-sectional view of the semiconductor device of the third embodiment. FIG. 17 is the DD' cross-section of FIGS. 18 and 19.

FIG. 18 is a partial schematic top view of the semiconductor device of the third embodiment. FIG. 18 shows the layout pattern of the gate electrode and the silicon carbide region on the side of the first surface of the silicon carbide layer.

FIG. 19 is a partial schematic top view of the semiconductor device of the third embodiment. FIG. 19 shows the layout pattern of the silicon carbide region on the side of the first surface of the silicon carbide layer. FIG. 19 is a view excluding the gate electrode from FIG. 18.

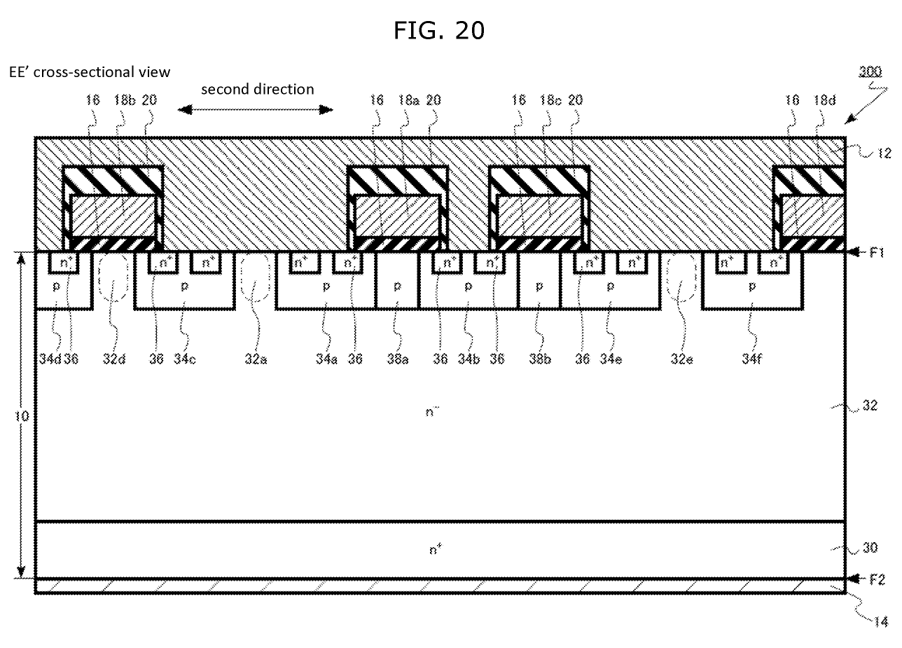

FIG. 20 is a partial schematic cross-sectional view of the semiconductor device of the third embodiment. FIG. 20 is the EE' cross-section of FIGS. 18 and 19.

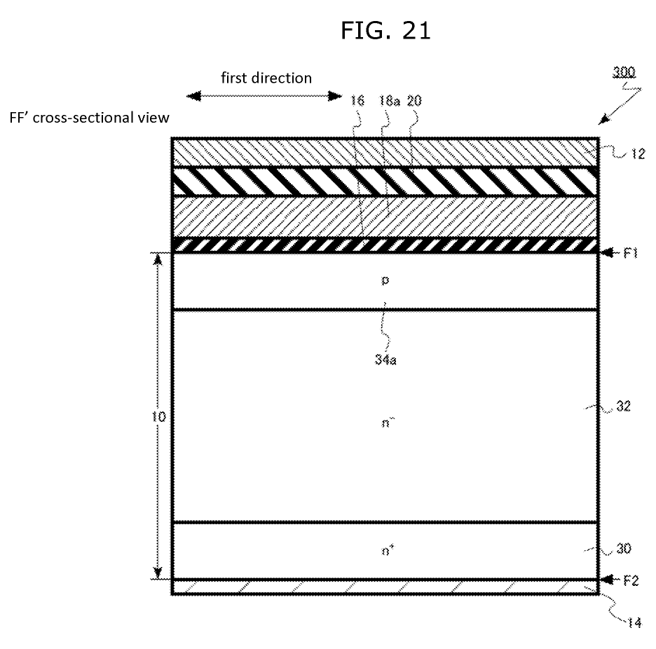

FIG. 21 is a partial schematic cross-sectional view of the semiconductor device of the third embodiment. FIG. 21 is the FF' cross-section of FIGS. 18 and 19.

FIGS. 17 and 20 are cross-sections perpendicular to the first direction. FIG. 21 is a cross-section perpendicular to the second direction.

MOSFET 300 includes a silicon carbide layer 10, a source electrode 12, a drain electrode 14, a gate insulating layer 16, a first gate electrode 18a, a second gate electrode 18b, a third gate electrode 18c, a fourth gate electrode 18d, and an interlayer insulating layer 20.

Hereinafter, the first gate electrode 18a, the second gate electrode 18b, the third gate electrode 18c, and the fourth gate electrode 18d may be individually or collectively referred to simply as the gate electrode 18.

The silicon carbide layer 10 includes an n+ type drain region 30, an n- type drift region 32, a p-type first base region 34a, a p-type second base region 34b, a p-type third base region 34c, a p-type fourth base region 34d, a p-type fifth base region 34e, a p-type sixth base region 34f, an n+ type source region 36, a p-type first intermediate region 38a, and a p-type second intermediate region 38b.

The drift region 32 includes a first portion 32a, a fourth portion 32d, and a fifth portion 32e.

Hereinafter, the first base region 34a, the second base region 34b, the third base region 34c, the fourth base region 34d, the fifth base region 34e, and the sixth base region 34f may be individually or collectively referred to simply as the base region 34. Also, the first intermediate region 38a and the second intermediate region 38b may be individually or collectively referred to simply as the intermediate region 38.

The fourth portion 32d of the drift region 32 is in contact with the first surface F1. The fourth portion 32d extends in the first direction.

In the second direction, the third base region 34c is provided between the fourth portion 32d and the first portion 32a. In the second direction, the fourth portion 32d is provided between the third base region 34c and the fourth base region 34d.

The intermediate region 38 is not provided between the third base region 34c and the fourth base region 34d.

The fourth portion 32d functions as the on-current path when MOSFET 300 is in the on-state.

The drift region 32 is not provided between the first base region 34a and the second base region 34b.

In summary, according to the third embodiment, it is possible to improve the surge current tolerance in the MOSFET provided with the SBD, similar to the first embodiment.

It is also possible to combine the components of MOSFET 110 of the first modification, MOSFET 120 of the second modification, or MOSFET 200 of the second embodiment with MOSFET 300 of the third embodiment.

In the first to third embodiments, the case where the first conductivity type is n-type and the second conductivity type is p-type has been described as an example, but it is also possible to make the first conductivity type p-type and the second conductivity type n-type.

In the first to third embodiments, the case of 4H-SiC as the crystal structure of SiC has been described as an example, but the present invention can also be applied to devices using other crystal structures of SiC such as 6H-SiC, 3C-SiC, etc. It is also possible to apply a surface other than the (0001) surface to the surface of the silicon carbide layer 10.

In the first to third embodiments, aluminum (Al) is given as the example of the p-type impurity, but boron (B) can also be used. Also, nitrogen (N) and phosphorus (P) have been given as examples of the n-type impurities, but arsenic (As), antimony (Sb), etc. can also be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device comprising:
a first electrode;
a second electrode;
a silicon carbide layer provided between the first electrode and the second electrode, having a first surface on the side of the first electrode and a second surface on the side of the second electrode, and including:
a first silicon carbide region of a first conductivity type, including a first portion extending in a first direction parallel to the first surface and in contact with the first electrode;
a second silicon carbide region of a second conductivity type, provided between the first silicon carbide region and the first surface, extending in the first direction and electrically connected to the first electrode;
a third silicon carbide region of the second conductivity type, provided between the first silicon carbide region and the first surface, extending in the first direction, and provided in a second direction perpendicular to the first direction and parallel to the first surface, relative to the second silicon carbide region such that the second silicon carbide region is between the first portion and the third silicon carbide region, and electrically connected to the first electrode;
a fourth silicon carbide region of the second conductivity type, provided between the first silicon carbide region and the first surface, extending in the first direction, and provided in the second direction relative to the second silicon carbide region such that the first portion is between the second silicon carbide region and the fourth silicon carbide region, and electrically connected to the first electrode;
a fifth silicon carbide region of the first conductivity type, provided between the second silicon carbide region and the first surface, and electrically connected to the first electrode; and
a sixth silicon carbide region of the second conductivity type, provided between the first silicon carbide region and the first surface, provided between the second silicon carbide region and the third silicon carbide region, and in contact with the second silicon carbide region and the third silicon carbide region;
a first gate electrode extending in the first direction, facing the second silicon carbide region, the third silicon carbide region, and the sixth silicon carbide region; and
a gate insulating layer provided between the first gate electrode and the second silicon carbide region, between the first gate electrode and the third silicon carbide region, and between the first gate electrode and the sixth silicon carbide region.

2. The semiconductor device according to claim 1, wherein a first depth of the sixth silicon carbide region from the first surface is shallower than a second depth of the second silicon carbide region based on the first surface.

3. The semiconductor device according to claim 2, wherein the first depth of the sixth silicon carbide region from the first surface is shallower than a third depth of the third silicon carbide region based on the first surface.

4. The semiconductor device according to claim 3, wherein the first depth is between two-thirds and nine-tenths of either the second depth or the third depth.

5. The semiconductor device according to claim 1, wherein an impurity concentration of the second conductivity type in the sixth silicon carbide region is lower than an impurity concentration of the second conductivity type in either the second silicon carbide region or the third silicon carbide region.

6. The semiconductor device according to claim 1,
wherein the first silicon carbide region further includes a second portion extending inwardly from the first surface,
wherein the second portion is provided between the second silicon carbide region and the third silicon carbide region,
wherein the sixth silicon carbide region is arranged alongside the second portion in the first direction, and
wherein the first gate electrode is facing the second portion.

7. The semiconductor device according to claim 6,
wherein the first silicon carbide region further includes a third portion extending inwardly from the first surface,
wherein the third portion is provided between the second silicon carbide region and the third silicon carbide region,
wherein the sixth silicon carbide region is provided between the second portion and the third portion in the first direction, and
wherein the first gate electrode is facing the third portion.

8. The semiconductor device according to claim 1, further comprising:
a second gate electrode extending in the first direction and facing the fourth silicon carbide region,
wherein the first silicon carbide region further includes a fourth portion extending inwardly from the first surface and in the first direction,
wherein the fourth silicon carbide region is provided between the fourth portion and the first portion, and
wherein the second gate electrode is facing the fourth portion.

9. The semiconductor device according to claim 8, wherein the first gate electrode faces only the second silicon carbide region, the third silicon carbide region, and the sixth silicon carbide region.

10. The semiconductor device according to claim 8, further comprising:
an eighth silicon carbide region of the second conductivity type provided between the first silicon carbide region and the first surface, extending in the first direction, and electrically connected to the first electrode,
wherein the fourth portion is between the fourth silicon carbide region and the eighth silicon carbide region, and
wherein the second gate electrode is facing the eighth silicon carbide region.

11. The semiconductor device according to claim 10, further comprising:
a ninth silicon carbide region of the second conductivity type provided between the first silicon carbide region and the first surface, provided between the fourth silicon carbide region and the eighth silicon carbide region, and in contact with the fourth silicon carbide region and the eighth silicon carbide region.

12. The semiconductor device according to claim 11, wherein the fourth portion and the ninth silicon carbide region are aligned in the first direction.

13. The semiconductor device according to claim 12,
wherein an impurity concentration of the second conductivity type in the sixth silicon carbide region is lower than an impurity concentration of the second conductivity type in either the second silicon carbide region or the third silicon carbide region, and
wherein an impurity concentration of the second conductivity type in the ninth silicon carbide region is lower than an impurity concentration of the second conductivity type in either the fourth silicon carbide region or the eighth silicon carbide region.

14. The semiconductor device according to claim 12, further comprising:
a seventh silicon carbide region of the first conductivity type provided between the ninth silicon carbide region and the first surface.

15. The semiconductor device according to claim 1,
wherein the first silicon carbide region further includes a fifth portion extending in the first direction and in contact with the first electrode, and
wherein the second silicon carbide region, the third silicon carbide region, and the sixth silicon carbide region are provided between the first portion and the fifth portion in the second direction.

16. The semiconductor device according to claim 1, wherein the sixth silicon carbide region extends inwardly from the first surface.

17. The semiconductor device according to claim 1, further comprising:
a seventh silicon carbide region of the first conductivity type provided between the sixth silicon carbide region and the first surface.

18. The semiconductor device according to claim 17, wherein an impurity concentration of the first conductivity type in the seventh silicon carbide region is lower than an impurity concentration of the first conductivity type in the fifth silicon carbide region.

19. A semiconductor device comprising:
a first electrode;
a second electrode;
a first semiconductor region of a first conductivity type provided between the first electrode and the second electrode;
a second semiconductor region of a second conductivity type provided between the first electrode and the first semiconductor region;
a first gate electrode facing the second semiconductor region; and
a second gate electrode facing the first semiconductor region,
wherein a part of the first semiconductor region contacts the first electrode, and
wherein the second gate electrode does not face the second semiconductor region.

20. The semiconductor device according to claim 19, further comprising:
a third semiconductor region of the second conductivity type provided between the first electrode and the first semiconductor region;
a fourth semiconductor region of the second conductivity type provided between the first electrode and the first semiconductor region;
a fifth semiconductor region of the first conductivity type provided between the first electrode and the third semiconductor region; and
a sixth semiconductor region of the first conductivity type provided between the first electrode and the fourth semiconductor region,
wherein the second semiconductor region is provided between the third semiconductor region and the fourth semiconductor region.
